(19) United States
(12) Patent Application Publication
(10) Pub. No.: US 2021/0204439 A1
(43) Pub. Date: Jul. 1, 2021

(54) HEAT CONDUCTING DEVICE WITH PERMEABILITY

(71) Applicant: SUZHOU TIANMAI THERMAL TECHNOLOGY CO., LTD., Suzhou (CN)

(72) Inventor: Xingqiang DING, Suzhou (CN)

(21) Appl. No.: 16/078,029

(22) PCT Filed: Feb. 27, 2018
(86) PCT No.: PCT/CN2018/077352

§ 371 Date: Aug. 21, 2018

(30) Foreign Application Priority Data
Mar. 9, 2017 (CN) 201710137594.4

(51) Int. Cl. H05K 7/20

(52) U.S. Cl. CPC H05K 7/2039

(57) ABSTRACT

The present invention provides a heat conducting device with permeability, comprising a heat conducting base which is a metal heat conducting base, a graphite heat conducting base, or an alloy heat conducting base, and the heat conducting base is provided with a magnetic conducting seam which extends through two surfaces in thickness direction of the heat conducting base. The heat conducting device with permeability provided in the present invention uses graphite, metals, or alloys having shielding property and excellent heat conducting property as a heat conducting base, and by opening a magnetic conducting seam on the heat conducting base to relieve the shielding effect to the signals, the heat conducting device has both excellent heat conducting property and magnetic permeability, and can be applied to electronic products that have magnetic permeability requirements, thereby promoting the development of electronic products to be ultra-thin.

### FIELD OF THE INVENTION

The invention relates to the technical field of heat conduction materials, and more particularly to a heat conducting device with permeability.

### BACKGROUND OF THE INVENTION

With the rapid development of science and technology, electronic products have entered the ultra-thin era. In order to make electronic products ultra-thin, an important problem to be solved is heat dissipation. One of the main ways of heat dissipation is to conduct heat generated by the parts of the electronic products through a heat conducting substrate. Heat conductivity coefficient is used to evaluate the heat conducting effect of the heat conducting substrate. The greater the heat conductivity coefficient, the better the heat conducting effect is. It is found that the heat conductivity coefficient of graphite is 150-1500 W/m·K, the heat conductivity coefficient of common metals is 70-500 W/m·K, and the heat conductivity coefficient of common metal alloys is 40-500 W/m·K. As compared with other commonly used heat conducting materials (such as rubber, plastics, etc.), graphite, metals and alloys have excellent heat conducting property. However, graphite, metals and alloys have shielding effects to electromagnetic signals, and electromagnetic signals exposed to the heat conducting substrates made of graphite, metals and alloys will be shielded and cannot be propagated properly, causing that graphite, metals and alloys with excellent heat conducting property cannot be used as heat conducting materials for electronic products with antenna (charging antenna coils, NFC antenna coils, etc.), thus, electronic products with antenna have to use the heat conducting substrate with poor heat conducting property such as plastics or rubbers, to increase the area or thickness of the heat conducting substrates for achieving the same heat conducting efficiency, and this hinders the progress of ultra-thin development of electronic products.

### SUMMARY OF THE INVENTION

In order to solve the above technical problems, the present invention provides a heat conducting device with permeability. In the invention, graphite, a metal, or an alloy having shielding property and excellent heat conducting property are used as a heat conducting base of a heat conducting device. By opening a magnetic conducting seam on the heat conducting base to relieve the shielding effect to the signals, the heat conducting device has both excellent heat conducting property and magnetic permeability, and can be applied to heat-conducting electronic products that have magnetic permeability requirements, thereby promoting the development of ultra-thin electronic products.

The invention provides a heat conducting device with permeability, such that the current problem that graphite, metal and alloy bases cannot balance heat conducting and magnetic permeability can be overcome. The device not only has excellent heat conducting property, but also relieves the signal shielding effect, so that graphite, metal and alloy materials can be used as a heat conducting base in electronic products, promoting the development of ultra-thin electronic products.

For the above purpose, the invention utilizes the following technical solution.

A heat conducting device with permeability comprises a heat conducting base, the heat conducting base is one of a metal heat conducting base, a graphite heat conducting base, and an alloy heat conducting base, and the heat conducting base is provided with a magnetic conducting seam, which extends through two surfaces of the heat conducting base in thickness direction of the heat conducting base.

In a preferred embodiment of the present invention, the magnetic conducting seam has a width of 1 um to 1 mm.

In a preferred embodiment of the present invention, the magnetic conducting seam is a linear magnetic conducting seam.

In a preferred embodiment of the present invention, the magnetic conducting seam is a grid magnetic conducting seam.

In a preferred embodiment of the present invention, there exist several magnetic conducting seams spaced apart, and a space between two adjacent magnetic conducting seams is 1 um to 20 mm.

In a preferred embodiment of the present invention, the heat conducting base has a thickness of 5 um to 5000 um.

In a preferred embodiment of the present invention, the metal heat conducting base is one of a copper heat conducting base, an aluminum heat conducting base, and a silver heat conducting base.

In a preferred embodiment of the present invention, the alloy heat conducting base is one of a copper alloy heat conducting base, an aluminum alloy heat conducting base, and a silver alloy heat conducting base.

In a preferred embodiment of the present invention, the heat conducting device with permeability further comprises a substrate on which the heat conducting base is attached.

As compared the prior art, the invention has the following advantages: the heat conducting device with permeability provided in the present invention uses graphite, a metal or an alloy having shielding property and excellent heat conducting property as a heat conducting base of a heat conducting device, and by opening a magnetic conducting seam on the heat conducting base to relieve the shielding effect to the signals, the heat conducting device has both excellent heat conducting property and magnetic permeability, and can be applied to heat-conducting electronic products that have magnetic permeability requirements, thereby promoting the ultra-thin development of electronic products.

### BRIEF DESCRIPTION OF THE DRAWINGS

In order to illustrate the technical solutions in the embodiments of the present invention more clearly, the accompanying drawings used in the embodiments will be described simply. Obviously, the accompanying drawings described hereinafter only are some embodiments of the present invention, and other drawings also can be obtained without creative work for those skilled in the art.

FIG. 1 is a schematic view of a first embodiment of the present invention;

FIG. 2 is a schematic view of a second embodiment of the present invention;

wherein, 2—heat conducting base, 4—magnetic conducting seam, 6—substrate.

### DETAILED DESCRIPTION OF THE EMBODIMENTS

The technical solutions in the embodiments of the present invention will be clearly and completely described in the following with reference to the accompanying drawings. It is obvious that the described embodiments are only illustrative and are not intended to limit the protection scope of the invention. Based on the embodiments of the present invention, all the other embodiments obtained by those skilled in the art without creative work are within the protection scope of the present invention.

### Embodiment 1

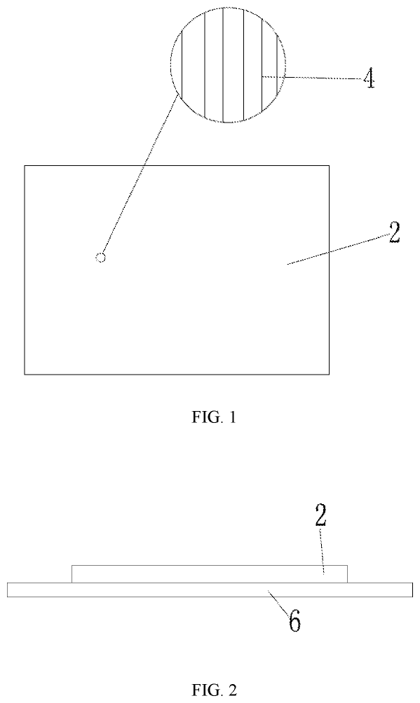

As shown in FIG. 1, the present embodiment discloses a heat conducting device with permeability, the device comprises a heat conducting base 2. The above heat conducting base 2 is one of a metal heat conducting base, a graphite heat conducting base, and an alloy heat conducting base. Preferably, the metal heat conducting base is one of a copper heat conducting base, an aluminum heat conducting base and a silver heat conducting base. The silver conducting base has the best heat conducting property, followed by the copper heat conducting base, but the copper heat conducting base is cheaper than the silver heat conducting base. The alloy heat conducting base is preferably one of a copper alloy heat conducting base, an aluminum alloy heat conducting base, and a silver alloy heat conducting base. In the present invention, the heat conducting base can be metal, graphite or alloy with plate-shaped, sheet-like or tubular structure, which all have excellent heat conducting property. The above heat conducting base 2 is provided with a magnetic conducting seam 4, which extends through two surfaces of the heat conducting base in thickness direction of the heat conducting base. In the heat conducting device with permeability provided in the present invention, graphite, a metals, or an alloy having shielding property and excellent heat conducting property are used as a heat conducting base of a heat conducting device, and a magnetic conducting seam is opened on the heat conducting base to relieve the shielding effect to the signals, such that the heat conducting device has both excellent heat conducting property and magnetic permeability, and can be applied to heat-conducting electronic products that have magnetic permeability requirements.

In order to make the electronic products to be ultra-thin, the thickness of the heat conducting base 2 of the present invention is controlled to be 5 um to 5000 um. The magnetic conducting seam 4 of the present invention can be obtained by an etching process, a laser engraving process or a die-cut process, wherein the magnetic conducting seams on the metal heat conducting base and the alloy heat conducting base can be formed by the etching process or the laser engraving process, and the magnetic conducting seams on the graphite heat conducting base can be formed by the die-cut process. The magnetic conducting seam 4 of the present invention can be a linear magnetic conducting seam or a grid magnetic conducting seam. When a linear magnetic conducting seam is used, there exist several magnetic conducting seams 4 spaced apart from each other on the heat conducting base 2, and by controlling the process, it can be achieved that a space between two adjacent magnetic conducting seams is 1 um to 20 mm and the magnetic conducting seam has a width of 1 um to 1 mm. A heat conducting base 2 obtained by the above processes has the best magnetic conducting property without deteriorating its excellent heat conducting property.

### Embodiment 2

As shown in FIG. 2, in the present embodiment, a heat conducting device with permeability is disclosed, the device comprises a substrate 6 and a heat conducting base 2 of the embodiment 1. The heat conducting base 2 is attached onto the surface of the substrate 6. In the heat conducting device of the present invention, the heat conducting base 2 can be installed separately for use or can be attached to the substrate 6, and the substrate 6 can facilitate the installation of the heat conducting base 2.

The abovementioned description of the disclosed embodiments enables those skilled in the art to implement or use the present invention. Multiple modifications to these embodiments are obvious to those skilled in the art, and general principles defined herein can be implemented in other embodiments without departing from the spirit or scope of the present invention. Therefore, the present invention will not be limited to theses embodiments illustrated herein, but needs to be in line with the widest scope consistent with the principles and novel features disclosed herein.

1. A heat conducting device with permeability, comprising a heat conducting base, wherein the heat conducting base is provided with a magnetic conducting seam which extends through two surfaces of the heat conducting base in thickness direction thereof, the heat conducting base being selected from the group consisting of a metal heat conducting base, a graphite heat conducting base and an alloy heat conducting base.

2. The heat conducting device with permeability according to claim 1, wherein the magnetic conducting seam has a width of 1 um to 1 mm.

3. The heat conducting device with permeability according to claim 2, wherein the magnetic conducting seam is a linear magnetic conducting seam.

4. The heat conducting device with permeability according to claim 2, wherein the magnetic conducting seam is a grid magnetic conducting seam.

5. The heat conducting device with permeability according to claim 3, wherein there exist several magnetic conducting seams spaced apart, and a space between two adjacent magnetic conducting seams is 1 um to 20 mm.

6. The heat conducting device with permeability according to claim 1, wherein the heat conducting base has a thickness of 5 um to 5000 um.

7. The heat conducting device with permeability according to claim 1, wherein the metal heat conducting base is a copper heat conducting base, an aluminum heat conducting base or a silver heat conducting base.

8. The heat conducting device with permeability according to claim 1, wherein the alloy heat conducting base is a copper alloy heat conducting base, an aluminum alloy heat conducting base or a silver alloy heat conducting base.

9. The heat conducting device with permeability according to claim 6, wherein the device further comprises a substrate on which the heat conducting base is attached.
